(19) United States
(12) Patent Application Publication
(10) Pub. No.: US 2024/0186175 A1
(43) Pub. Date: Jun. 6, 2024

(54) SUBSTRATE TRANSFER APPARATUS AND SUBSTRATE TRANSFER METHOD

(71) Applicant: KABUSHIKI KAISHA YASKAWA DENKI, Fukuoka (JP)

(72) Inventors: Takashi MINAMI, Fukuoka (JP); Yoshiki KIMURA, Fukuoka (JP); Hiroki SANEMASA, Fukuoka (JP)

(21) Appl. No.: 18/510,394

(22) Filed: Nov. 15, 2023

(30) Foreign Application Priority Data
Dec. 2, 2022 (JP) 2022-193251

(51) Int. Cl. H01L 21/687; B25J 11/00; B25J 19/02; H01L 21/68

(52) U.S. Cl. CPC H01L 21/68707; B25J 11/0095; B25J 19/021; H01L 21/681

(57) ABSTRACT

A substrate transfer apparatus includes a hand that transfers a substrate from a cassette that accommodates substrates in multiple stages in a vertical direction; a movement mechanism that moves the hand; a controller that controls the movement mechanism; and a first detection unit that detects the substrate. The controller includes an offset amount change unit that changes an offset amount by which the hand is moved up and down from a substrate support height of the cassette when the hand loads and unloads the substrate with respect to the cassette, according to a thickness or a deflection amount of the substrate detected by the first detection unit.

### CROSS-REFERENCE TO RELATED APPLICATIONS

This application is based on and claims priority from Japanese Patent Application No. 2022-193251 filed on Dec. 2, 2022 with the Japan Patent Office, the disclosure of which is incorporated herein in its entirety by reference.

### TECHNICAL FIELD

The present disclosure relates to a substrate transfer apparatus and a substrate transfer method.

### BACKGROUND

Transfer apparatuses have been known in the related art, transferring substrates such as wafers and panels to and from a cassette that holds the substrates by using a robot with a hand.

For example, a technique has been proposed, which detects the possibility of contact between a robot and a wafer accommodated in a cassette by the sensor provided in a wafer transfer arm or a cassette (see, e.g., Japanese Patent Laid-Open Publication No. 2007-234936).

### SUMMARY

In the related art described above, when the state of the substrate that has already been accommodated in the cassette changes due to various substrate processing such as stacking processing or due to deflection, there is a possibility the accommodated substrate comes into contact with the robot or a newly loaded substrate.

An aspect of an embodiment is to provide a substrate transfer apparatus and a substrate transfer method capable of preventing damage to the substrate due to contact even when the state of the substrate changes.

According to an aspect of an embodiment, a substrate transfer apparatus includes a hand that transfers a substrate from a cassette that accommodates substrates in multiple stages in a vertical direction: a movement mechanism that moves the hand: a controller that controls the movement mechanism; and a first detection unit that detects the substrate. The controller includes an offset amount change unit that changes an offset amount by which the hand is moved up and down from a substrate support height of the cassette when the hand loads and unloads the substrate with respect to the cassette, according to a thickness or a deflection amount of the substrate detected by the first detection unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic top view illustrating the outline of a substrate transfer apparatus.

FIG. 2 is an explanatory diagram of an offset amount upon loading.

FIG. 3 is an explanatory diagram of an offset amount upon unloading.

FIG. 4 is a diagram illustrating a configuration example of a robot.

FIG. 5 is a schematic front view of a cassette.

FIG. 6 is a schematic top view pf the cassette.

FIG. 7 is an explanatory diagram of a vertical mapping operation.

FIG. 8 is an explanatory diagram of a horizontal mapping operation.

FIG. 9 is a block diagram of the substrate transfer apparatus.

FIG. 10 is an explanatory diagram of substrate information.

FIG. 11 is an explanatory diagram (part 1) of an offset change process.

FIG. 12 is an explanatory diagram (part 2) of the offset change process.

FIG. 13 is a flowchart illustrating the processing procedure of a loading process.

FIG. 14 is a flowchart illustrating the processing procedure of an unloading process.

### DETAILED DESCRIPTION

In the following detailed description, reference is made to the accompanying drawing, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, a substrate transfer apparatus and a substrate transfer method of the present disclosure will be described in detail with reference to the drawings. The present disclosure is not limited to the embodiments described herein below.

Further, in the embodiments described herein below, expressions such as “parallel,” “front,” “parallel,” and “intermediate” may be used, but these conditions may not be strictly satisfied. That is, the expressions may allow deviations in, for example, manufacturing accuracy, installation accuracy, processing accuracy, and detection accuracy.

### (Outline of Substrate Transfer Apparatus 1)

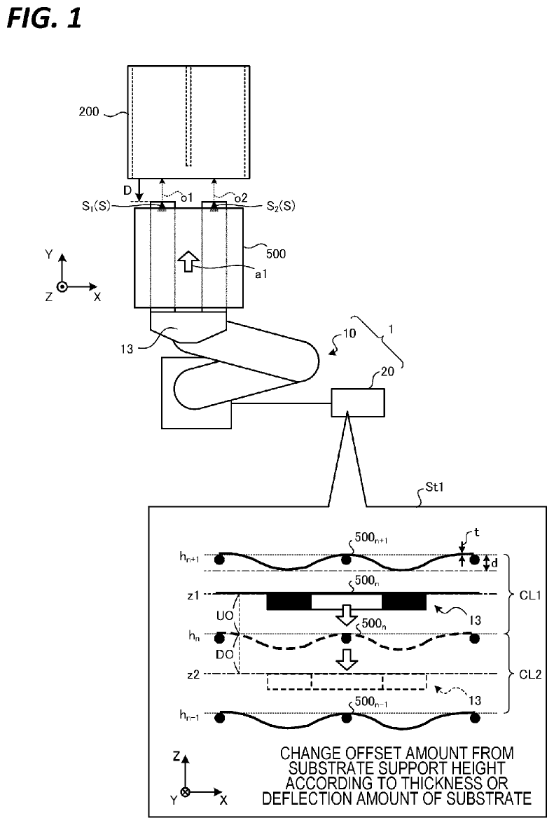

First, an outline of a substrate transfer apparatus 1 according to an embodiment will be described with reference to FIG. 1. FIG. 1 is a schematic top view illustrating the outline of the substrate transfer apparatus 1. In order to facilitate the understanding of the descriptions, FIG. 1 illustrates a three-dimensional orthogonal coordinate system with a Z axis having the vertical upward direction as a positive direction, an X axis parallel to a horizontal direction along the front side of a cassette 200 on which a substrate 500 is placed, and an Y axis parallel to a depth direction of the cassette 500. The orthogonal coordinate system may also be illustrated in other drawings used in the following descriptions.

Further, the front side of the cassette 200 refers to a lateral side of the cassette 200 that has an opening into which a hand 13 for transferring a substrate 500 is capable of being inserted. Further, the depth direction of the cassette 200 refers to a direction in which the hand 13 is advanced into or retreated from the front side of the cassette 200 in order to load and unload the substrate 500.

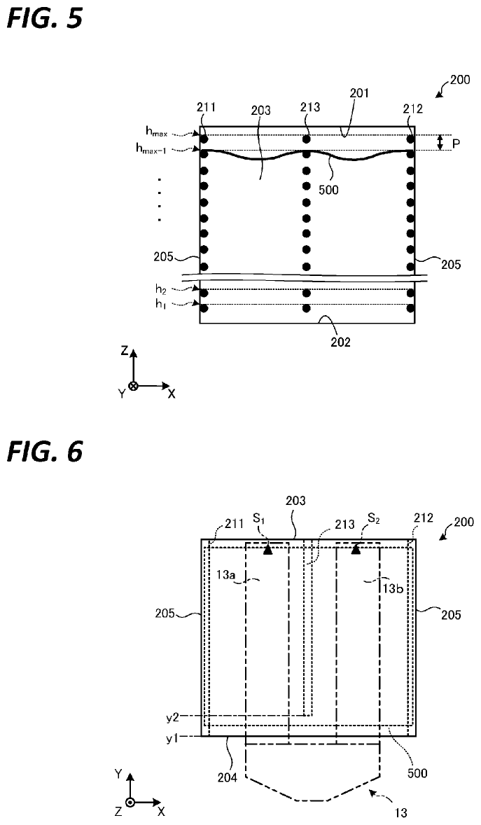

The cassette 200 has a plurality of support portions extending in an insertion direction (Y-axis direction) of the hand 13 (see, e.g., the dashed lines illustrated in the cassette 200). A configuration example of the cassette 200 will be described later with reference to FIGS. 5 and 6.

Further, FIG. 1 illustrates a front schematic view of a target substrate 500ₙ, which is to be loaded into the cassette 200, in a state of being carried into a slot at a substrate support height hₙ, as viewed from the front side (negative direction of Y-axis) of the cassette 200 (see, e.g., step St1).

Hereinafter, as illustrated in the front schematic view, the substrate 500 to be loaded and unloaded will be appropriately referred to as a “target substrate 500ₙ” (n is a natural number of 2 or more). It is assumed that the target substrate 500ₙ is supported within the cassette 200 in a slot having a substrate support height hₙ. Further, accordingly, the substrate 500 accommodated in a slot immediately above the target substrate 500ₙ in the cassette 200, that is, a slot at a substrate support height hₙ₊₁, is appropriately referred to as an “immediately-above substrate 500ₙ₊₁.” Similarly, the substrate 500 accommodated in a slot immediately below the target substrate 500ₙ, that is, a slot at a substrate support height hₙ₋₁, is appropriately referred to as an “immediately-below substrate 500ₙ₋₁.” When it is not necessary to distinguish these substrates, the substrate is simply referred to as a “substrate 500.”

The front schematic view depicts that the substrate 500 is deflected, by drawing the substrate 500 in a wavy manner. The substrate 500 may be illustrated in the same manner in drawings other than FIG. 1 that will be described later. In addition, the black circles in the front schematic view correspond to the above-described support portions that support the substrate 500 from below.

Furthermore, in the present embodiment, the placement site for the substrates 500 is mainly exemplified with the cassette 200 that accommodates the substrates 500 in multiple stages, but the placement site for the substrates 500 may be an aligner that adjusts the orientation of the substrates 500 or various processing apparatuses that perform various types of substrate processing on the substrates 500. Further, in this embodiment, the substrate 500 is a panel such as a substrate of resin material (e.g., glass epoxy) or a glass substrate having a rectangular outer shape, but the substrate 500 may be a wafer having a circular outer shape or a thin plate of any shape and any material.

As illustrated in FIG. 1, the substrate transfer apparatus 1 includes a robot 10 and a controller 20 that controls the operation of the robot 10. The robot 10 includes a hand 13 that transfers a substrate 500, and a movement mechanism that moves the hand 13.

Further, the hand 13 includes a sensor S (sensor S1 and sensor S2) that detects an object such as the cassette 200 and the substrate 500 in the cassette 200. The sensor S is, for example, a reflective laser sensor. The sensor S irradiates scanning lines o1 and o2 toward the front (Y-axis direction) at a predetermined detectable distance D from the front side of the cassette 200 illustrated in FIG. 1. Further, the sensor S detects the reflected line that the scanning lines o1 and o2 return after being reflected by the cassette 200 and the substrate 500 in the cassette 200, thereby detecting the presence or absence and the position of the object.

FIG. 1 illustrates a case where the sensor S is provided at each branch of the hand 13 whose distal end side is branched into two (the number of the sensors S is two), but the number of the sensors may be one. Further, when the distal end side of the hand 13 is branched into three or more, the sensor S may be provided at each branched portion. That is, the hand 13 may be provided with the same number of sensors S as the number of branches.

The controller 20 stores teaching information including a substrate support height (Z coordinate) at a placement position (XY coordinate) of the substrate 500. Further, when loading and unloading the substrate 500 at the placement height, the controller 20 performs a mapping process to determine, based on the scanning result of the sensor S, whether the hand 13 is capable of being advanced into or retreated from the cassette 200 without the hand 13 or the substrate 500 held by the hand 13 coming into contact with other substrates 500 in the cassette 200.

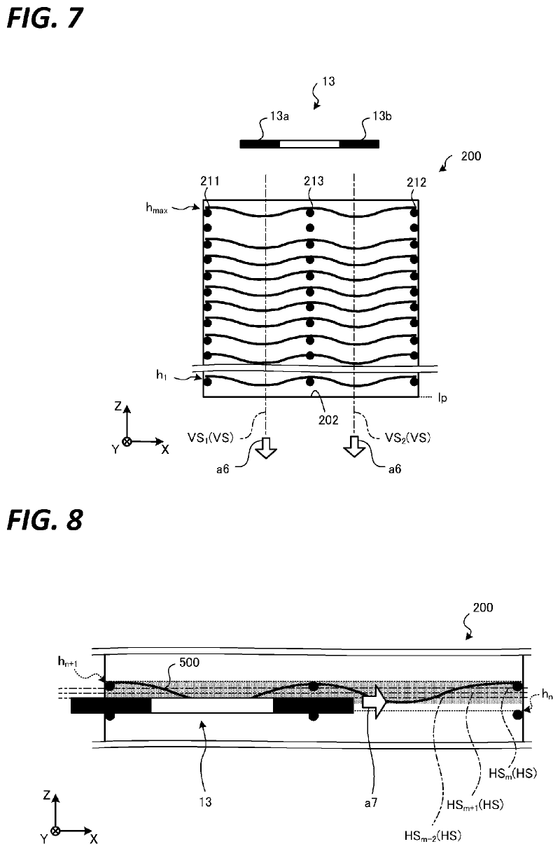

In the mapping process, the controller 20 causes the robot 10 to perform a predetermined mapping operation, thereby detecting the presence or absence of the substrate 500 in each slot in the cassette 200, the actual thickness, and the actual deflection amount by the sensor S. A specific example of the mapping operation will be described later with reference to FIGS. 7 and 8.

Then, the controller 20 changes the offset amount from the substrate support height h according to the thickness or deflection amount of the substrate 500 obtained by the mapping process (step St1).

Specifically, as illustrated in the front schematic diagram of step St1, when the target substrate 500ₙ is loaded to the substrate support height hₙ, the controller 20 first advances the hand 13 holding the target substrate 500ₙ into the clearance CL1 between the substrate support height hₙ₊₁ and the substrate support height hₙ. At this time, the controller 20 advances the hand 13 at, for example, a planned advance height z1. The planned advance height z1 is calculated from an upward offset amount UO from the substrate support height hₙ.

The controller 20 stores, in advance, substrate information that defines at least the relationship between the thickness of the substrate 500 and the deflection amount of the substrate 500 for each type of substrate 500 to be transferred, and the specified value of the upward offset amount UO is calculated based on, for example, the substrate information.

Further, after being advanced into the clearance CL1, the controller 20 moves down the hand 13 and causes the hand 13 to place the target substrate 500ₙ in the slot at the substrate support height hₙ. After placing, the controller 20 moves down the hand 13 to a clearance CL2 between the substrate support height hₙ and a substrate support height hₙ₋₁.

At this time, the controller 20 moves down the hand 13 to, for example, a planned retreat height z2. The planned retreat height z2 is calculated from a downward offset amount DO from the substrate support height hₙ. The specified value of the downward offset amount DO is calculated, for example, based on the above-mentioned substrate information in the same manner as the upward offset amount UO. Then, the controller 20 moves down the hand 13 to the planned retreat height z2, and then retreats the hand 13 from the cassette 200.

However, when the upward offset amount UO and the downward offset amount DO remain at fixed values, there is a concern that the hand 13 may not be able to be advanced at the planned advance height z1 or moved down to the planned retreat height z2 in a case where the substrate 500 already stored in the cassette 200 has undergone various substrate processes and the thickness t has changed or the deflection amount d has increased.

Therefore, in the substrate transfer method according to the embodiment, the controller 20 changes the offset amount from the substrate support height h according to the thickness or deflection amount of the substrate 500 obtained by the mapping process.

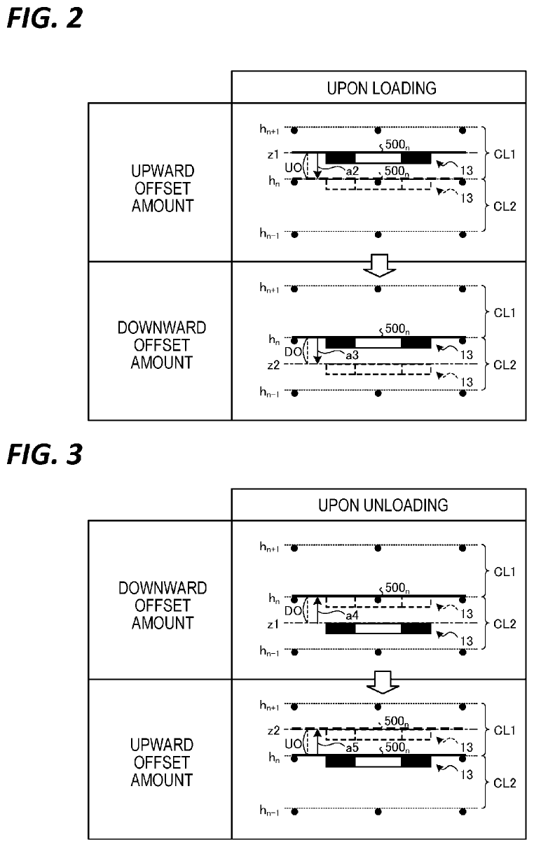

FIG. 2 is an explanatory diagram of an offset amount upon loading. Further, FIG. 3 is an explanatory diagram of an offset amount upon unloading.

To summarize the offset amount, first, as illustrated in FIG. 2, when the target substrate 500ₙ is loaded into the cassette 200, the offset amount includes an upward offset amount UO that is an amount by which the hand 13 is moved down to the substrate support height hₙ (see, e.g., arrow a2 in FIG. 2), and a downward offset amount DO that is an amount by which the hand 13 is moved down from the substrate support height hₙ (see, e.g., arrow a3 in FIG. 2).

During the loading, the controller 20 changes the upward offset amount UO or the downward offset amount DO from the substrate support height hₙ according to the thickness or deflection amount of the substrate 500, and determines the planned advance height z1 in clearance CL1 by the changed upward offset amount UO. Further, the controller 20 determines the planned retreat height z2 in the clearance CL2 by the changed downward offset amount DO.

Further, as illustrated in FIG. 3, when the target substrate 500, is unloaded from the cassette 200, the offset amount includes a downward offset amount DO that is an amount by which the hand 13 is moved up to the substrate support height hₙ (see, e.g., arrow a4 in FIG. 3), and an upward offset amount UO that is an amount by which the hand 13 is moved up from the substrate support height hₙ (see, e.g., arrow a5 in FIG. 3).

During the unloading, the controller 20 changes the downward offset amount DO or the upward offset amount UO from the substrate support height hₙ according to the thickness or deflection amount of the substrate 500, and determines the planned advance height z1 in clearance CL2 by the changed downward offset amount DO. Further, the controller 20 determines the planned retreat height z2 in the clearance CL1 by the changed upward offset amount UO.

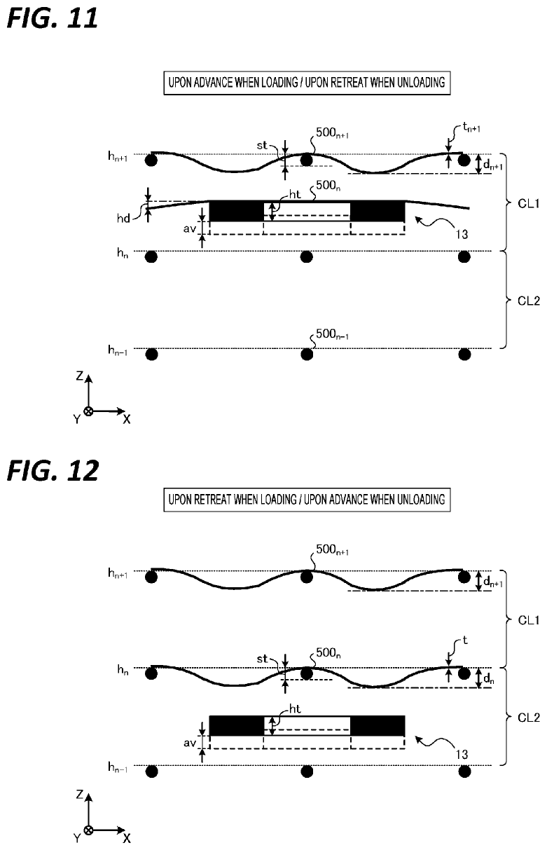

The controller 20 may change the offset amount by further taking into account, for example, the preset thickness or deflection amount for each type of the substrate 500, the thickness of the hand 13, the deflection amount of the hand 13, the vibration width of the hand 13, the thickness of the support portion described above, and the like without being limited to the actual thickness or actual deflection amount of the substrate 500 obtained through the mapping process. This point will be described later with reference to FIGS. 11 and 12.

Thus, the substrate transfer apparatus 1 according to the embodiment changes the offset amount by which the hand 13 is moved up and down from the substrate support height h of the cassette 200 when the hand 13 loads and unloads the substrate 500 into and from the cassette 200, according to the thickness or deflection amount of the substrate 500 detected by the sensor S.

Therefore, according to the substrate transfer apparatus 1 according to the embodiment, damage to the substrate 500 due to contact may be prevented even when the state of the substrate 500 changes.

### Configuration Example of Robot 10

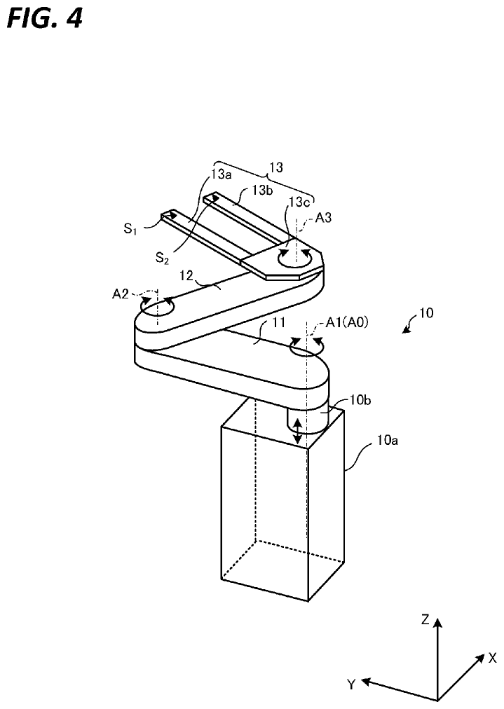

Next, a configuration example of the robot 10 illustrated in FIG. 1 will be described with reference to FIG. 4. FIG. 4 is a diagram illustrating a configuration example of the robot 10. FIG. 4 corresponds to a perspective view of the robot 10 as viewed obliquely from above.

As illustrated in FIG. 4, the robot 10 is, for example, a horizontally articulated robot having a horizontally articulated SCARA arm and a lift mechanism. The robot 10 includes a body portion 10a, a lift portion 10b, a first arm 11, a second arm 12, and a hand 13. The body portion 10a is fixed to, for example, a bottom surface of the transfer chamber for the substrate 500, and incorporates a lift mechanism for moving up and down the lift portion 10b.

The lift portion 10b moves up and down along a lift axis A0 and supports the proximal end side of the first arm 11 so as to be rotatable around a first axis A1. The lift portion 10b itself may be rotated around the first axis A1. Alternatively, the first axis A1 may be positioned closer to the negative direction of the Y-axis direction on the upper surface of the lift portion 10b. The first arm 11 may be made longer by positioning the first axis A1 closer to the negative direction of the Y-axis direction in the same drawing.

The first arm 11 supports the proximal end side of the second arm 12 on the distal end side so as to be rotatable around a second axis A2. The second arm 12 supports the proximal end side of the hand 13 on the distal end side so as to be rotatable around a third axis A3.

Thus, the robot 10 is a horizontally articulated robot including three links of the first arm 11, the second arm 12, and the hand 13. Thus, the robot 10 may freely transfer the substrate 500 in the horizontal direction.

Further, as described above, the robot 10 includes the lift portion 10b and the body portion 10a that move up and down the lift portion 10b. Thus, it is possible to access each substrate 500 accommodated in multiple stages in the cassette 200, and to acquire the presence and absence or the deflection amount of each accommodated substrate 500 by moving the hand 13. The body portion 10a, the lift portion 10b, the first arm 11, and the second arm 12 correspond to an example of an “movement mechanism” that moves the hand 13 in the horizontal direction and the vertical direction.

The hand 13 includes a first fork portion 13a, a second fork portion 13b, and a base portion 13c. The first fork portion 13a and the second fork portion 13b are branched from the base portion 13c and extend to face each other with a gap therebetween.

The first fork portion 13a and the second fork portion 13b support the substrate 500 from below when the substrate 500 is transferred. The first fork portion 13a and the second fork portion 13b have a holding mechanism (not illustrated) that employs, for example, a contact adsorption method, a non-contact adsorption method, or a grasping method, and hold and support the substrate 500 by the holding mechanism.

Further, as illustrated in FIG. 4, a sensor S1 and a sensor S2 are provided on the distal end sides of the upper surfaces of the first fork portion 13a and the second fork portion 13b, respectively.

### Configuration Example of Cassette 200

Next, the cassette 200 illustrated in FIG. 1 will be described with reference to FIGS. 5 and 6. FIG. 5 is a schematic front view of the cassette 200. Further, FIG. 6 is a schematic top view of the cassette 200. In FIG. 6, the hand 13 at a delivery position of the substrate 500 in the cassette 200 is indicated by a two-dot chain line.

As illustrated in FIG. 5, the front side of the cassette 200 is open, and max-stage slots are provided between top surface 201 and a bottom side 202 inside the cassette 200, each of which may accommodate a substrate 500. “max” is a natural number of 2 or more. Each slot is provided with a first support portion 211, a second support portion 212, and a third support portion 213 extending in a direction along the depth direction of the cassette 200 (Y-axis direction).

Each slot supports the substrate 500 at the substrate support height h. At the first stage counting from the bottom side 202, the substrate 500 is supported at a substrate support height h₁. At the second stage, the substrate 500 is supported at a substrate support height h₂. At the (max−1)-th stage, the substrate 500 is supported at the substrate support height hₘₐₓ₋₁. At the max-th stage, the substrate 500 is supported at the substrate support height hₘₐₓ. In addition, it is assumed that a pitch P between slots is equal.

The first support portion 211 and the second support portion 212 are provided on the lateral side 205 inside the cassette 200. Further, the third support portion 213 is provided at an intermediate position between the first support portion 211 and the second support portion 212 in the horizontal direction (X-axis direction) of the cassette 200. That is, the cassette 200 supports the substrate 500 at three points when viewed from the front side. Although FIG. 5 illustrates a case where there is one third support portion 213, for example, two or more third support portions 213 may be provided such that the intervals between the supports are equal.

Here, as illustrated in FIG. 6, the third support portion 213 is a rod-shaped (bar-shaped) member extending from a rear side 203 of the cassette 200 toward the front side 204 of the cassette 200, and its front end is closer to the rear side 203 of the cassette 200 than front ends of the support portion 211 and the second support portion 212. That is, the extension length of the third support portion 213 in the depth direction (Y-axis direction) is shorter than the extension lengths of the first support portion 211 and the second support portion 212.

As described above, when the front end of the third support portion 213 is short, the front side of the substrate 500 supported by the third support portion 213 may droop, but the sensor S detects deflection amount of the substrate 500 including the drooping.

Further, as illustrated in FIG. 6, the hand 13 includes a first fork portion 13a that is insertable between the first support portion 211 and the third support portion 213, and a second fork portion 13b that is insertable between the second support portion 212 and the third support portion 213. As described above, when two or more third support portions 213 are provided, the hand 13 may be provided with a number of extensions that may be inserted between the respective support portions.

As described above, the cassette 200 includes the first support portion 211 and the second support portion 212 that support both ends of the substrate 500, respectively, when viewed from the front side 204 of the cassette 200. Further, the cassette 200 includes the third support portion 213 that supports the substrate 500 at an intermediate position between the first support portion 211 and the second support portion 212.

Further, the hand 13 includes at least the first fork portion 13a that may be advanced between the first support portion 211 and the third support portion 213, and the second fork portion 13b that may be advanced between the second support portion 212 and the third support portion 213. The sensors S (sensor S1 and sensor S2) are provided on the distal end sides of the first fork portion 13a and the second fork portion 13b of the hand 13, respectively.

### (Explanation of Vertical Mapping Operation)

Next, among the mapping operations for detecting the thickness and deflection amount of the substrate 500, a vertical mapping operation will be described with reference to FIG. 7. FIG. 7 is an explanatory diagram of a vertical mapping operation.

In the vertical mapping process, the controller 20 (see, e.g., FIG. 1) moves the hand 13 close to the cassette 200 up to a detectable distance D of the sensor S, and positions the hand 13 above the front side 204 of the cassette 200, as illustrated in FIG. 7.

Then, the controller 20 moves down the hand 13. At this time, the controller 20 moves the hand 13 along the Z-axis direction (see, e.g., arrow a6 in the figure) and causes the sensor S to perform the vertical scanning along a trajectory VS. Further, the controller 20 moves the hand 13 until the scanning range of the sensor S1 by the vertical scanning reaches at least the bottom side 202 of the cassette 200. It is not necessary to move the hand 13 until the hand 13 reaches the bottom side 202. For example, in combination with the horizontal mapping operation described below, it may be unnecessary to move the hand 13 until the hand 13 reaches the bottom side 202.

Then, based on the scanning result of the sensor S, the controller 20 detects and records the presence or absence of the substrate 500 in each slot of the cassette 200.

Further, based on the scanning result of the sensor S, the controller 20 detects and records the thickness of the substrate 500 in each slot where the substrate 500 is present.

Further, based on the scanning result of the sensor S, the controller 20 detects and records the deflection amount of the substrate 500 in each slot where the substrate 500 is present. The deflection amount may be detected as a difference between each substrate support height h and the lowest stage position of each substrate 500. When the deflection amount on a trajectory VS1 is different from that on a trajectory VS2, the larger value is detected as the deflection amount of the corresponding substrate 500.

Although FIG. 7 illustrates an example in which the hand 13 is moved down from above the front side 204 of the cassette 200, it is possible to move up the hand 13 from below the front side 204, thereby causing the sensor S to perform vertical scanning along the trajectory VS.

### (Explanation of Horizontal Mapping Operation)

Next, among the mapping operations for detecting the thickness and deflection amount of the substrate 500, a horizontal mapping operation will be described with reference to FIG. 8. FIG. 8 is an explanatory diagram of a horizontal mapping operation.

In the horizontal mapping process, the controller moves the hand 13 close to the cassette 200 up to a detectable distance D of the sensor S, and aligns the hand 13 to the substrate support height h of each slot, as illustrated in FIG. 8.

Then, the controller 20 horizontally moves the hand 13 (see, e.g., arrow a7 in FIG. 8) and causes the sensor S to perform the horizontal scanning along a trajectory HS. At this time, the controller 20 moves the hand 13 horizontally while moving down the hand 13 appropriately to repeat the horizontal scanning for each slot, for example, over a predetermined scanning range (see the filled portion in FIG. 8) from the substrate support height h of each slot (see trajectory HSₘ to trajectory HSₘ₊₂ (m is a natural number of 1 or more) in FIG. 8).

Further, the controller 20 moves the hand 13 until the scanning range of the sensor S1 by the horizontal scanning reaches, for example, the bottom side 202 of the cassette 200. It is not necessary to move the hand 13 until the scanning range of the sensor S by the horizontal scanning reaches the bottom side 202. For example, when the sensor S no longer detects the substrate 500, the detection of the deflection amount is completed. The clearance may be determined, for example, from information regarding the external shape of the cassette 200 stored in the storage unit 21, which will be described later.

Then, based on the scanning result of the sensor S, the controller 20 detects and records the presence or absence of the substrate 500 in each slot of the cassette 200. Further, based on the scanning result of the sensor S, the controller 20 detects and records the thickness of the substrate 500 in each slot of the cassette 500 where the substrate 500 is present.

Further, based on the scanning result of the sensor S, the controller 20 detects and records the detection amount of the substrate 500 in each slot of the cassette 500 where the substrate 500 is present. The deflection amount may be detected in the same manner as in the vertical mapping operation.

The mapping operation may be performed only in the vertical direction illustrated in FIG. 7, may be performed only in the horizontal direction illustrated in FIG. 8, or may be performed in combination of both directions.

### Configuration Example of Controller 20

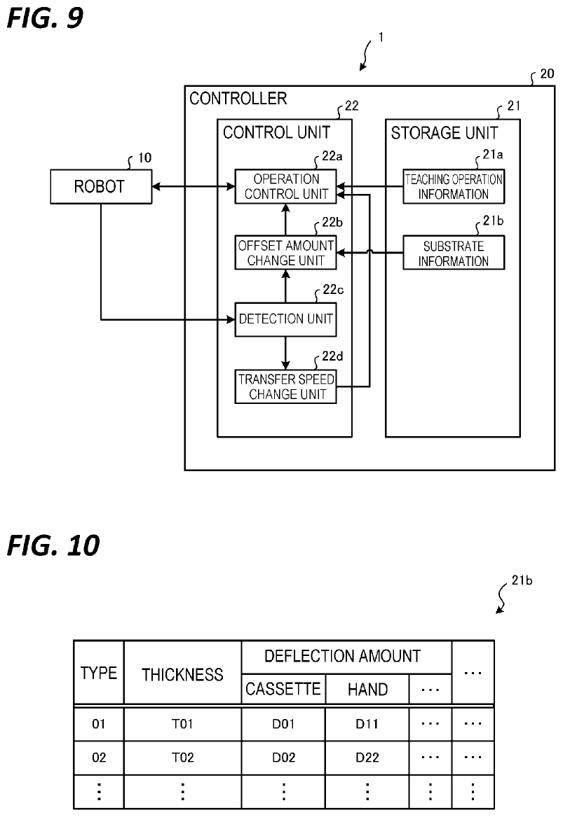

Next, a configuration example of the substrate transfer apparatus 1 illustrated in FIG. 1 will be described with reference to FIG. 9. FIG. 9 is a block diagram of the substrate transfer apparatus 1. As described above, the substrate transfer apparatus 1 includes the robot 10 and the controller 20 that controls the operation of the robot 10. Since the configuration example of the robot 10 has already been described with reference to FIG. 4, the configuration of the controller 20 will be mainly described here.

As illustrated in FIG. 9, the controller 20 includes a storage unit 21 and a control unit 22. The storage unit 21 corresponds to, for example, a random access memory (RAM) or a hard disk drive (HDD). The storage unit 21 also stores teaching information 21a and substrate information 21b.

The teaching information 21a is information generated in the teaching step of teaching the robot 10 to perform operations, and including “jobs” that define the operation of the robot 10 including the movement trajectory of the hand 13. The teaching information 21a generated by another computer connected by a wired or wireless network may be stored in the storage unit 21.

Further, the teaching information 21a may include information specifying the type of the substrate 500 to be transferred, information regarding the external shape of the cassette 200, and information regarding the teaching position in the cassette 200 (e.g., substrate support height (Z coordinate) at the placement position (XY coordinate) of each substrate 500).

The substrate information 21b is information that defines the relationship between the thickness of the substrate 500 and the deflection amount of the substrate 500 for each type of substrate 500, as described above. FIG. 10 is an explanatory diagram of the substrate information 21b.

As illustrated in FIG. 10, the substrate information 21b is a table that defines the relationship between at least the “thickness” of the substrate 500 and the “deflection amount” for each “type” of substrate 500. The “deflection amount” may be defined for each deflection amount, for example, when the substrate 500 is supported by the “cassette” or by the “hand.”

The “thickness” is defined based on, for example, catalog values for the thickness of the substrate 500. The “deflection amount” is defined based on, for example, catalog values for the deflection of the substrate 500 or measurements obtained through experiments.

The description will refer back to FIG. 9. The control unit 22 includes an operation control unit 22a, an offset amount change unit 22b, a detection unit 22c, and a transfer speed change unit 22d. Further, the controller 20 is connected to the robot 10.

Here, the controller 20 includes, for example, a computer having a central processing unit (CPU), a read only memory (ROM), a random access memory (RAM), a hard disk drive (HDD), an input/output port, or various circuits.

The CPU of the computer functions as the operation control unit 22a, the offset amount change unit 22b, the detection unit 22c, and the transfer speed change unit 22d of the control unit 22 by reading and executing, for example, programs stored in the ROM. Further, at least one or all of the operation control unit 22a, the offset amount change unit 22b, the detection unit 22c, and the transfer speed change unit 22d of the control unit 22 may be configured by hardware such as an application specific integrated circuit (ASIC) or a field programmable gate array (FPGA).

Further, the controller 20 may acquire the programs described above or various kinds of information via another computer or a portable recording medium connected by a wired or wireless network.

The operation control unit 22a controls the movement of the robot 10 based on the teaching information 21a, the offset amount changed by the offset amount change unit 22b, and the transfer speed changed by the transfer speed change unit 22d.

Specifically, the operation control unit 22a instructs actuators corresponding to the axes of the robot 10 based on the teaching information 21a stored in the storage unit 21, thereby causing the robot 10 to perform the mapping operation or an operation to transfer the substrate 500. Further, the operation control unit 22a performs feedback control using encoder values of the actuators, thereby improving the operation accuracy of the robot 10.

Further, the operation control unit 22a advances or retreat the hand 13 to or from the cassette 200 based on the offset amount changed by the offset amount change unit 22b. Further, the operation control unit 22a moves the hand 13 at a transfer speed changed by the transfer speed change unit 22d.

The offset amount change unit 22b changes the offset amount based on the substrate information 21b and the detection result by the detection unit 22c. The offset amount changing unit 22b calculates a specified value of the offset amount based on, for example, the substrate information 21b before the mapping operation is performed.

Further, the offset amount change unit 22b changes the offset amount based on the actual thickness t and the actual deflection amount d of each substrate 500 detected by the detection unit 22c.

For example, by performing the mapping operation, the offset amount change unit 22b estimates the deflection amount of the substrate 500 from the actual thickness t of the substrate 500 detected by the sensor S, and changes the offset amount based on the estimated deflection amount.

Further, for example, the offset amount change unit 22b compares the actual thickness t of the substrate 500 detected by the detection unit 22c with the substrate information 21b, and estimates the corresponding deflection amount as the estimated deflection amount.

For example, when the actual deflection amount d of the substrate 500 is detected by the sensor S by performing the mapping operation, the offset amount change unit 22b changes the offset amount based on the larger value of the actual deflection amount d and the estimated deflection amount.

Further, for example, the offset amount change unit 22b changes the offset amount based on at least one of the actual deflection amount of the immediately-above substrate 500ₙ₊₁ or the actual deflection amount of the immediately-below substrate 500ₙ₋₁, which is detected by the mapping operation.

Further, for example, the offset amount change unit 22b changes the offset amount based on a hand characteristic value including at least one of the deflection amount or the vibration width of the hand 13 when the hand 13 is moved up or down.

The detection unit 22c detects the actual thickness t and actual deflection amount d of each substrate 500 in the cassette 200 based on the scanning result of the sensor S when the robot 10 performs the mapping operation.

The offset change process will be described in detail with reference to FIGS. 11 and 12. FIGS. 11 and 12 are explanatory diagrams (parts 1 and 2) of the offset change process. Further, FIG. 11 illustrates the time of advance upon loading or the time of retreat upon unloading. Meanwhile, FIG. 12 illustrates the time of retreat upon loading or the time of advance upon unloading.

In FIG. 11, the case of loading will be described as an example. When the target substrate 500ₙ is loaded to the substrate support height hₙ of the cassette 200, as illustrated in FIG. 11, it is assumed that the hand 13 is advanced into the clearance CL1 while supporting the target substrate 500ₙ.

In this case, the offset amount change unit 22b calculates the upward offset amount UO based on a deflection amount dₙ₊₁ of the immediately-above substrate 500ₙ₊₁ detected by the detection unit 22c, the thickness ht of the hand 13, and the hand characteristic value av. The hand characteristic value includes at least one of the deflection amount or the vibration width of the hand 13.

Here, the deflection amount of the target substrate 500ₙ supported by the hand 13 is defined as a deflection amount hd. The deflection amount hd is obtained, for example, from the substrate information 21b. At this time, the planned advance height z1 into the clearance CL1 is derived from the formula (substrate support height hₙ+upward offset amount UO+deflection amount hd).

Further, it is assumed that the thickness of each of the first support portion 211, the second support portion 212, and the third support portion 213 is a thickness st. Then, when (actual deflection amount dₙ₊₁ of immediately-above substrate 500ₙ₊₁>support thickness st), it is possible to determine whether the hand 13 is capable of being advanced into the clearance CL1, depending on whether the condition ((substrate support height hₙ₊₁−deflection amount dₙ₊₁)−substrate support height hₙ−thickness t of substrate 500−upward offset amount UO−hand characteristic value av>0) is satisfied,

Further, when (deflection amount dₙ₊₁ of immediately-above substrate 500ₙ₊₁≤support thickness st), it is possible to determine whether the hand 13 is capable of being advanced into the clearance CL1, depending on whether the condition (substrate support height hₙ₊₁−substrate support height hₙ−thickness st of support portion−thickness t of substrate 500−upward offset amount UO−hand characteristic value av>0) is satisfied,

Further, it is possible to determine whether the hand 13 is capable of being advanced into the clearance CL1 depending on whether the condition (upward offset amount UO−deflection amount hd of target substrate 500ₙ−hand characteristic value av>0) is satisfied.

Thus, when the hand 13 loads the target substrate 500 to the substrate support height hₙ of the target substrate 500ₙ, the offset amount change unit 22b changes the upward offset amount UO based on the actual deflection amount dₙ₊₁ of the immediately-above substrate 500ₙ₊₁, the thickness ht of the hand 13, and the hand characteristic value av, so that the hand 13 is capable of being advanced into the clearance CL1 between the substrate support height hₙ of the target substrate 500ₙ and the substrate support height hₙ₊₁ of the immediately-above substrate 500ₙ₊₁.

Meanwhile, in the case of unloading, when the hand 13 unloads the target substrate 500ₙ from the substrate support height hₙ of the target substrate 500ₙ, the offset amount change unit 22b changes the upward offset amount UO based on the actual deflection amount dₙ₊₁ of the immediately-above substrate 500ₙ₊₁, the thickness ht of the hand 13, and the hand characteristic value av, so that the hand 13 is capable of being retreated from the clearance CL1 between the substrate support height hₙ of the target substrate 500ₙ and the substrate support height hₙ₊₁ of the immediately-above substrate 500ₙ₊₁.

Next, in FIG. 12, the case of unloading will be described as an example. When the target substrate 500ₙ is unloaded from the substrate support height hₙ of the cassette 200, as illustrated in FIG. 12, it is assumed that the hand 13 is advanced into the clearance CL2 without supporting the substrate 13.

In this case, the offset amount change unit 22b calculates the downward offset amount DO based on a deflection amount dₙ of the target substrate 500ₙ detected by the detection unit 22c, the thickness ht of the hand 13, and the hand characteristic value av.

Based on this, the planned advance height z1 into the clearance CL2 is derived from the formula (substrate support height hₙ+downward offset amount DO+actual deflection amount dₙ).

Then, it is possible to determine whether the hand 13 is capable of being advanced into the clearance CL2, depending on whether the condition ((substrate support height hₙ−deflection amount dₙ)−(substrate support height hₙ₋₁−thickness t of substrate 500)−thickness ht of hand 13−hand characteristic value av>0) is satisfied.

Thus, when the hand 13 unloads the target substrate 500ₙ from the substrate support height hₙ of the target substrate 500ₙ, the offset amount change unit 22b changes the downward offset amount DO based on the actual deflection amount dₙ of the target substrate 500ₙ, the thickness ht of the hand 13, and the hand characteristic value av, so that the hand 13 is capable of being advanced into the clearance CL2 between the substrate support height hₙ of the target substrate 500, and the substrate support height hₙ₋₁ of the immediately-below substrate 500ₙ₋₁.

Meanwhile, in the case of loading, when the hand 13 loads the target substrate 500ₙ to the substrate support height hₙ of the target substrate 500ₙ, the offset amount change unit 22b changes the downward offset amount DO based on the actual deflection amount dₙ of the target substrate 500ₙ, the thickness ht of the hand 13, and the hand characteristic value av, so that the hand 13 is capable of being retreated from the clearance CL2 between the substrate support height hₙ of the target substrate 500, and the substrate support height hₙ₋₁ of the immediately-below substrate 500ₙ₋₁.

In FIG. 12, for convenience of explanation, the clearance CL2 between the slot of the substrate support height hₙ and the slot of substrate support height hₙ₋₁ is used as an example. However, when changing the downward offset amount DO, the slot at the substrate support height hₙ₋₁ is not necessarily the target to be considered for the slot at the substrate support height hₙ. For example, when there is no substrate 500 in the slot at the substrate support height hₙ₋₁, but there is a substrate 500 in the slot at the substrate support height hₙ₋₂ which is one stage below, that would be the target to be considered. In other words, in the case of the downward offset amount DO, the target is an immediately-below slot in the sense that the substrate 500 exists for the slot at the substrate support height hₙ, i.e., the slot at a substrate support height hₙ₋ₚ (p is a natural number of 1 or more), and the “immediately-below substrate” may be expressed as an immediately-below substrate 500ₙ₋ₚ. Further, the clearance CL2 is a clearance between the slot at the substrate support height hₙ and the slot at the substrate support height hₙ₋ₚ.

The description will refer back to FIG. 9. The transfer speed change unit 22d changes the transfer speed by the hand 13 based on the thickness t and deflection amount d of each substrate 500 detected by the detection unit 22c. For example, when the thickness of the substrate 500 is smaller than a predetermined threshold value, the transfer speed change unit 22d slows down the transfer speed. Further, for example, when the deflection amount of the substrate 500 is larger than a predetermined threshold value, the transfer speed change unit 22d slows down the transfer speed.

### (Processing Procedure)

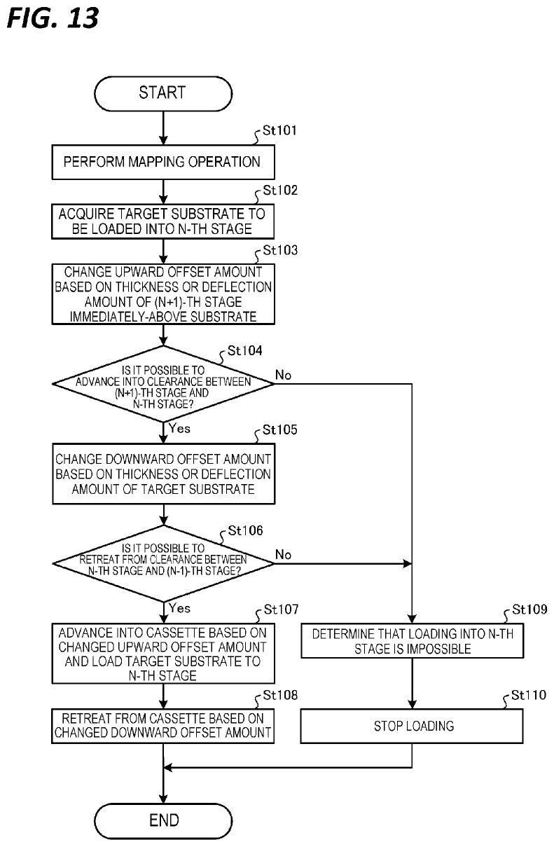

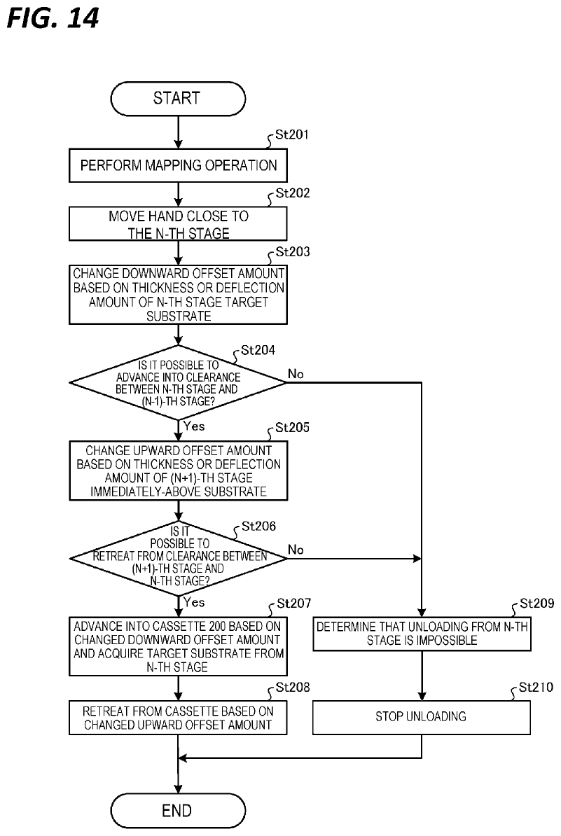

Next, each processing procedure of the loading process and the unloading process executed by the substrate transfer apparatus 1 will be described with reference to FIGS. 13 and 14.

The loading process will be first described. FIG. 13 is a flowchart illustrating the processing procedure of the loading process. FIG. 13 illustrates a processing procedure when loading the target substrate 500ₙ into the n-th slot of the cassette 200.

As illustrated in FIG. 13, the robot 10 first performs a mapping operation under the control of the operation control unit 22a of the controller 20 (step St101). Then, the operation control unit 22a causes the robot 10 to acquire the target substrate 500ₙ to be loaded into the n-th stage from the aligner (step St102).

Then, based on the result of the mapping operation in step St101, the offset amount change unit 22b of the controller 20 changes the upward offset amount UO based on the thickness or deflection amount of the (n+1)-th stage immediately-above substrate 500ₙ₊₁ (step St103).

At this time, the offset amount change unit 22b determines whether the hand 13 is capable of being advanced into the clearance CL1 between the (n+1)-th stage and the n-th stage by changing the upward offset amount UO (step St104).

When it is determined that the hand 13 is capable of being advanced into the clearance CL1 (step St104, Yes), then the offset amount change unit 22b changes the downward offset amount DO based on the thickness or deflection amount of the target substrate 500ₙ (step St105).

Then, at this time, the offset amount change unit 22b determines whether the hand 13 is capable of being retreated from the clearance CL2 between the n-th stage and the (n−1)-th stage by changing the downward offset amount DO (step St106).

When it is determined that the hand 13 is capable of being retracted from the clearance CL2 (step St106, Yes), the operation control unit 22a controls the robot 10 such that the hand 13 is advanced into cassette 200 based on the upward offset amount UO changed in step St103 and loads the target substrate 500ₙ to the n-th stage (step St107).

Further, the operation control unit 22a controls the robot 10 such that the hand 13 is retreated from the cassette 200 based on the downward offset amount DO changed in step St105 (step St108). Then, the process is ended.

Further, when it is determined in step St104 that the hand 13 is incapable of being advanced into the clearance CL1 (step St104, No), or when it is determined in step St106 that the hand 13 is incapable of being retreated from the clearance CL2 (step St106, No), the operation control unit 22a determines that the target substrate 500, is incapable of being loaded into the n-th stage (step St109). Then, the operation control unit 22a stops loading the target substrate 500ₙ (step St110), and ends the process.

Next, the unloading process will be described. FIG. 14 is a flowchart illustrating the processing procedure of the unloading process. FIG. 14 illustrates a processing procedure when unloading the target substrate 500ₙ from the n-th slot of the cassette 200.

As illustrated in FIG. 14, the robot 10 first performs a mapping operation under the control of the operation control unit 22a of the controller 20 (step St201). Then, the operation control unit 22a controls the robot 10 to move the hand 13 close to the n-th slot (step St202).

Then, based on the result of the mapping operation in step St201, the offset amount change unit 22b of the controller 20 changes the downward offset amount DO based on the thickness or deflection amount of the n-th stage target substrate 500ₙ (step St203).

At this time, the offset amount change unit 22b determines whether the hand 13 is capable of being advanced into the clearance CL2 between the n-th stage and the (n−1)-th stage by changing the downward offset amount DO (step St204).

When it is determined that the hand 13 is capable of being advanced into the clearance CL2 (step St204, Yes), then the offset amount change unit 22b changes the upward offset amount UO based on the thickness or deflection amount of the (n+1)-th stage immediately-above substrate 500ₙ₊₁ (step St205).

Then, at this time, the offset amount change unit 22b determines whether the hand 13 is capable of being retreated from the clearance CL1 between the (n+1)-th stage and the n-th stage by changing the upward offset amount UO (step St206).

When it is determined that the hand 13 is capable of being retracted from the clearance CL1 (step St206, Yes), the operation control unit 22a controls the robot 10 such that the hand 13 is advanced into the cassette 200 based on the downward offset amount DO changed in step St203 and acquires the target substrate 500ₙ from the n-th stage (step St207).

Further, the operation control unit 22a controls the robot 10 such that the hand 13 is retreated from the cassette 200 based on the upward offset amount UO changed in step St105 (step St208). Then, the process is ended.

Further, when it is determined in step St204 that the hand 13 is incapable of being advanced into the clearance CL2 (step St204, No), or when it is determined in step St206 that the hand 13 is incapable of being retreated from the clearance CL1 (step St206, No), the operation control unit 22a determines that the target substrate 500ₙ is incapable of being unloaded from the n-th stage (step St209). Then, the operation control unit 22a stops unloading the target 500ₙ (step St210) and ends the process.

In FIGS. 13 and 14, as illustrated in steps St101 and St201, an example has been given in which the mapping operation is executed immediately before accessing each slot, but the mapping operation does not necessarily need to be executed immediately before each access. For example, it is possible to execute the mapping operation once at the beginning of a batch and access each slot based on the results of that single run.

### Summary

As described above, the substrate transfer apparatus 1 according to one aspect of the embodiment is a substrate transfer apparatus that loads and unloads a substrates 500 into and from a cassette 200 that accommodates substrates 500 in multiple stages in the vertical direction. The substrate transfer apparatus 1 includes a hand 13 that transfer the substrate 500, a movement mechanism that moves the hand 13, a controller 20 that controls the movement mechanism, and a sensor S (corresponding to an example of a “first detection unit”) that detects the substrate 500. The controller 20 includes an offset amount change unit 22b that changes an offset amount by which the hand is moved up and down from a substrate support height h of the cassette 200 when the hand 13 loads and unloads the substrate 500 with respect to the cassette 200, according to a thickness or a deflection amount of the substrate 500 detected by the sensor S.

Thus, by changing the offset amount according to the detected thickness or deflection amount of the substrate 500, it is possible to prevent damage to the substrate 500 due to contact even when the state of the substrate 500 changes.

Further, when the substrate 500 is unloaded from the cassette 200, the offset amount includes a downward offset amount DO that is an amount by which the hand 13 is moved up to the substrate support height h, and an upward offset amount UO that is an amount by which the hand 13 is moved up from the substrate support height h. Further, when the substrate 500 is loaded into the cassette 200, the offset amount includes an upward offset amount UO that is an amount by which the hand 13 is moved up to the substrate support height h, and a downward offset amount DO that is an amount by which the hand 13 is moved up from the substrate support height h.

Thus, each offset amount may be changed for each case of downward offset and upward offset.

Further, the sensor S is a reflective sensor provided in the hand 13, and the offset amount change unit 22b changes the offset amount based on an actual deflection amount of the substrate 500 detected by the reflective sensor when the hand 13 is moved in at least one of a vertical direction and a horizontal direction by the movement mechanism.

Thus, damage to the substrate 500 due to contact may be prevented according to the actual amount of deflection amount detected from the vertical direction and/or the horizontal direction.

Further, the offset amount change unit 22b changes the offset amount based on an estimated deflection amount of the substrate 500 estimated from the thickness of the substrate 500 detected by the sensor S.

Thus, damage to the substrate 500 due to contact may be prevented based on the estimated deflection amount estimated from the actual thickness.

Further, the controller 20 stores, in advance, substrate information 21b that defines at least a relationship between the thickness of the substrate 500 and the deflection amount of the substrate 500 for each type of the substrate 500, and the offset amount change unit 22b estimates the estimated deflection amount based on the substrate information 21b.

Thus, damage to the substrate 500 due to contact may be prevented based on the estimated deflection amount estimated from a table data based on experiments.

Further, the offset amount change unit 22b changes the offset amount based on a larger value of the actual deflection amount of the substrate 500 obtained using the sensor S and the estimated deflection amount.

Thus, the substrate 500 may be transferred more safely by adopting the larger value based on the comparison result between table data based on experiments and actual measured values.

Further, the offset amount change unit 22b changes the offset amount based on at least one of a deflection amount dₘ₊₁ of an immediately-above substrate 500ₙ₊₁ positioned immediately above a target substrate 500ₙ that is loaded and unloaded by the hand 13, and a deflection amount dₙ₋₁ of an immediately-below substrate 500ₙ₋₁ positioned immediately below the target substrate 500ₙ.

Thus, it is possible to transfer the substrate 500 more safely by changing the offset amount even while taking into consideration the conditions of the upper and lower stages of the processing target stage.

Further, for example, the offset amount change unit 22b changes the offset amount based on a hand characteristic value including at least one of a deflection amount hd or a vibration width of the hand 13 when the hand 13 is moved up or down.

Thus, by changing the offset amount while taking into account the characteristics of the hand 13 itself when the hand 13 is moved up or down, it is possible to transfer the substrate 500 more safely.

Further, when the target substrate 500, is loaded to the substrate support height hₙ of the target substrate 500ₙ by the hand 13, the offset amount change unit 22b changes the upward offset amount UO based on the actual deflection amount dₙ₊₁ of the immediately-above substrate 500ₙ₊₁, the thickness ht of the hand 13, and the hand characteristic value av, so that the hand 13 is capable of being advanced into the clearance CL1 between the substrate support height hₙ of the target substrate 500, and the substrate support height hₙ₊₁ of the immediately-above substrate 500ₙ₊₁.

Thus, by changing the upward offset amount UO such that the hand 13 is capable of being advanced into the clearance CL1 between the processing target stage and the immediately-above stage while taking into account the actual deflection amount dₙ₊₁ of the immediately-above substrate 500ₙ₊₁, the thickness ht of the hand 13, and the hand characteristic value av, it is possible to transfer the substrate 500 more safely.

Further, when the target substrate 500ₙ is unloaded from the substrate support height hₙ of the target substrate 500, by the hand 13, the offset amount change unit 22b changes the downward offset amount DO based on the actual deflection amount dₙ of the target substrate 500ₙ, the thickness ht of the hand 13, and the hand characteristic value av, so that the hand 13 is capable of being advanced into the clearance CL2 between the substrate support height hₙ of the target substrate 500, and the substrate support height hₙ₋₁ of the immediately-below substrate 500ₙ₋₁.

Thus, by changing the downward offset amount DO such that the hand 13 is capable of being advanced into the clearance CL2 between the processing target stage and the immediately-below stage while taking into account the actual deflection amount dₙ of the target substrate 500ₙ, the thickness ht of the hand 13, and the hand characteristic value av, it is possible to transfer the substrate 500 more safely.

Further, the cassette 200 includes a plurality of support portions that each support the substrate at a plurality of locations for each stage, when viewed from a front side 204 of the cassette 200. When the actual deflection amount dₙ₊₁ of the immediately-above substrate 500ₙ₊₁ is less than a thickness st of a support portion that supports the immediately-above substrate 500ₙ₊₁, the offset amount change unit 22b changes the upward offset amount UO based on the thickness st of the support portion instead of the actual deflection amount dₙ₊₁ of the immediately-above substrate 500ₙ₊₁.

Thus, by further changing the upward offset amount UO to advance the hand 13 while taking into consideration the thickness st of the support portion at the immediately-above stage, it is possible to transfer the substrate 500 more safely.

Further, the controller 20 further includes a transfer speed change unit 22d that changes a transfer speed of the substrate 500 by the hand 13 according to the thickness of the substrate 500.

Thus, by changing not only the offset amount but also the transfer speed according to the thickness of the substrate 500, it is possible to transfer the substrate 500 more safely.

An aspect of an embodiment is to provide a substrate transfer apparatus and a substrate transfer method capable of preventing damage to the substrate due to contact even when the state of the substrate changes.

From the foregoing, it will be appreciated that various embodiments of the present disclosure have been described herein for purposes of illustration, and that various Modifications may be made without departing from the scope and spirit of the present disclosure. Accordingly, the various embodiments disclosed herein are not intended to be limiting, with the true scope and spirit being indicated by the following claims.

What is claimed is:

1. A substrate transfer apparatus comprising:
a hand configured to transfer a substrate from a cassette that accommodates substrates in multiple stages in a vertical direction;
a mover configured to move the hand;
a controller configured to control the mover; and
a first detector configured to detect the substrate,
wherein the controller is further configured to change an offset amount by which the hand is moved up and down from a substrate support height of the cassette when the hand loads and unloads the substrate with respect to the cassette, according to a thickness or a deflection amount of the substrate detected by the first detector.

2. The substrate transfer apparatus according to claim 1, wherein the offset amount includes
when the substrate is unloaded from the cassette, a downward offset amount that is an amount by which the hand is moved up to the substrate support height, and an upward offset amount that is an amount by which the hand is moved up from the substrate support height, and
when the substrate is loaded to the cassette, an upward offset amount that is an amount by which the hand is moved down to the substrate support height, and an downward offset amount that is an amount by which the hand is moved down from the substrate support height.

3. The substrate transfer apparatus according to claim 1, wherein the first detector is a reflective sensor provided in the hand, and
the controller changes the offset amount based on an actual deflection amount of the substrate detected by the reflective sensor when the hand is moved in at least one of a vertical direction and a horizontal direction by the mover.

4. The substrate transfer apparatus according to claim 1, wherein the controller changes the offset amount based on an estimated deflection amount of the substrate estimated from the thickness of the substrate detected by the first detector.

5. The substrate transfer apparatus according to claim 4, wherein the controller
stores, in advance, substrate information that defines at least a relationship between the thickness of the substrate and the deflection amount of the substrate for each type of the substrate, and
estimates the estimated deflection amount based on the substrate information.

6. The substrate transfer apparatus according to claim 5, wherein the controller changes the offset amount based on a larger value of the actual deflection amount of the substrate obtained using the first detector and the estimated deflection amount.

7. The substrate transfer apparatus according to claim 2, wherein the controller changes the offset amount based on at least one of a deflection amount of an immediately-above substrate positioned immediately above a target substrate that is loaded and unloaded by the hand, and a deflection amount of an immediately-below substrate positioned immediately below the target substrate.

8. The substrate transfer apparatus according to claim 2, wherein the controller changes the offset amount based on a hand characteristic value including at least one of a deflection amount and a vibration width of the hand when the hand is moved up and down.

9. The substrate transfer apparatus according to claim 7, wherein the controller changes the offset amount based on a hand characteristic value including at least one of a deflection amount and a vibration width of the hand when the hand is raised or lowered.

10. The substrate transfer apparatus according to claim 9, wherein when the target substrate is loaded to the substrate support height of the target substrate by the hand, the controller changes the upward offset amount based on an actual deflection amount of the immediately-above substrate, a thickness of the hand, and the hand characteristic value, so that the hand is allowed to be advanced into a clearance between a substrate support height of the target substrate and the substrate support height of the immediately-above substrate.

11. The substrate transfer apparatus according to claim 9, wherein when the target substrate is unloaded from the substrate support height of the target substrate by the hand, the controller changes the downward offset amount based on an actual deflection amount of the target substrate, a thickness of the hand, and the hand characteristic value, so that the hand is allowed to be advanced into a clearance between a substrate support height of the target substrate and the substrate support height of the immediately-below substrate.

12. The substrate transfer apparatus according to claim 10, wherein the cassette includes a plurality of supports each configured to support the substrate at a plurality of locations for each stage, when viewed from a front side of the cassette, when the actual deflection amount of the immediately-above substrate is less than a thickness of a support that supports the immediately-above substrate, the controller changes the upward offset amount based on the thickness of the support instead of the actual deflection amount of the immediately-above substrate.

13. The substrate transfer apparatus according to claim 1, wherein the controller changes a transfer speed of the substrate by the hand according to the thickness of the substrate.

14. A substrate transfer method comprising:
providing a substrate transfer apparatus including:
a hand configured to transfer a substrate from a cassette that accommodates substrates in multiple stages in a vertical direction;
a mover configured to move the hand;
a controller configured to control the mover; and
a first detector configured to detect the substrate; and
changing an offset amount by which the hand is moved up and down from a substrate support height of the cassette when the hand loads and unloads the substrate with respect to the cassette, according to a thickness or a deflection amount of the substrate detected by the first detector.
